(19) United States
(12) Patent Application Publication
(10) Pub. No.: US 2018/0240956 A1
(43) Pub. Date: Aug. 23, 2018

(54) FLEXIBLE THERMOELECTRIC GENERATOR

(71) Applicant: Purdue Research Foundation, West Lafayette, IN (US)

(72) Inventors: Kazuaki Yazawa, West Lafayette, IN (US); Ali Shakouri, West Lafayette, IN (US)

(73) Assignee: Purdue Research Foundation, West Lafayette, IN (US)

(21) Appl. No.: 15/765,111

(22) PCT Filed: Sep. 30, 2016
(86) PCT No.: PCT/US16/55062

§ 371 Date: Mar. 30, 2018

Related U.S. Application Data
(60) Provisional application No. 62/235,025, filed on Sep. 30, 2015.

(51) Int. Cl. H01L 35/32; H01L 35/30; H01L 35/16

(52) U.S. Cl. CPC H01L 35/32; H01L 35/16; H01L 35/30

(57) ABSTRACT

A low heat flux flexible thermoelectric generator woven with semiconducting strings. The thermoelectric strings have a repeated structure of (metal)-(p-type semiconductor)-(metal)-(n-type semiconductor) materials and are formulated with a continuous structure forming a module. In this woven structure, the thermoelectric strings are the warp threads and the insulator strings are the weft yarns. The p-type and n-type stripes are aligned to the same dimensions. A metal terminal at the end of the strings provides the electrical connections in a series with a serpentine pattern. Two electrically insulating films laminated on the top and bottom of this woven structure conduct the surface heat to the metal junctions on both the hot and cold sides. The small fill factor (low fractional area coverage of the thermoelectric leg) creates a high internal thermal resistance that is better matched to low heat flux sources such as human body for harvesting the maximum power output.

### CROSS-REFERENCE TO RELATED APPLICATIONS

The present patent application is related to and claims the priority benefit of U.S. Provisional Patent Application Ser. No. 62/235,025, filed Sep. 30, 2015, the contents of which are hereby incorporated by reference in their entirety into the present disclosure.

### TECHNICAL FIELD

The present disclosure generally relates to thermoelectric devices, and in particular to a flexible thermoelectric generator utilizing semiconducting strings arranged in a woven structure.

### BACKGROUND

This section introduces aspects that may help facilitate a better understanding of the disclosure. Accordingly, these statements are to be read in this light and are not to be understood as admissions about what is or is not prior art.

Recent interest in wearable electronics and health care equipment has energized the development of flexible electronic packaging technologies. These devices are mostly operated by battery and require re-charging the battery or replacing it. Therefore, a local power supply with energy from the human body is desired. There are several ways to harvest human energy such as motion energy (vibration), piezoelectric, and heat. Thermoelectric generators are known as a solid-state energy conversion device and are theoretically applicable for this purpose. Since the energy source is the human body, there are significant boundary conditions for this source. 1) The available heat is limited to about 4 mW/cm² in static mode (e.g., when sitting on a chair). 2) The surface of the human body has a flexible three dimensional curvature. Hence, a conventional thermoelectric module with rigid structure and the ceramic substrate package do not easily adapt to this particular application. Lower heat flux requires a large internal thermal resistance (longer thermoelectric legs) to obtain the thermal impedance match. Therefore, a 3-D spacer may be needed to adapt to the curvature and this can further reduce the useful temperature delta across the thermoelectric elements.

For given temperatures at the heat source and ambient, an optimum thermal design is needed in order to obtain the maximum possible power output per unit area when the external electrical load is already matched. The internal thermal resistance across the thermoelectric leg should match \sqrt{1+Zr} times the sum of the external thermal resistances to the heat source and the heat sink. The human body dissipates approximately 4 mW/cm², while the heat flux varies depending on the location and the state of the activities. Considering a room temperature of 25° C. and a skin surface temperature of 35° C., the effective thermal resistance for the cold side of the generator is about 4 K.m²/W due to the natural air convection (ignoring the radiation heat transport). This is quite a low value and means that the length of the thermoelectric leg must be very large to match the optimum thermal resistance. Even with a significantly low thermal conductivity material, the optimum length could easily exceed a few centimeters. Hence, the prior art material and standard thermoelectric module geometry does not physically allow the output power to be maximized. The practical power output can be a fraction of the maximum available.

Curve fit to the body surface is the most significant challenge for current rigid body thermoelectric modules known in the art. Thermoelectric material for near room temperature (300K) applications is typically p- and n-type doped Bismuth-Telluride (Bi₂Te₃), which has a high figure-of-merit (ZT) of about 0.75-0.8. Recent research efforts on nanostructured materials have yielded double the ZT value for the bismuth-telluride based material, mostly reducing the thermal conductivity from about 3 W/m.K down to the range of 1.5 W/m.K, which allows the ZT value to achieve 1.5 in the materials used in commercial thermoelectric modules. As discussed above, it is desired that the thermal resistance of the thermoelectric leg matches the external thermal resistance with a heat source and heat sink. Even applying an aggressively small fill factor of 3%, the optimum leg length for maximum power is about 5 mm, while the smallest fill factor in the market (˜30%), requires 54 mm long legs. In reality, the practical length with a reasonable fill factor of 10% design yields less than 10% of the maximum potential.

In addition, known ceramic plate substrates in the module are not only electrically insulating and thermally concentrating received heat to the legs and spreading heat again to the cold side heat sink, but also secure the entire mechanical structure. This mechanical functionality is especially important for higher aspect ratio (longer legs) structures and will be thicker, which is completely opposed to the requirement to match the curvature.

Flexible thermoelectric modules are often implemented using organic materials. One advantage of organic materials is their naturally low thermal conductivity, and the electric conductivity can be modified drastically. Recent lab scale performance reported is in the ZT=0.5 range. There are challenges when attempting to manufacture such flexible thermoelectric legs in an array that uses the same physical arrangement as a conventional thermoelectric module. For example, automated pick and place fabrication is no longer adaptable for non-rigid legs. Furthermore, soldering at higher temperatures of 230-270° C. is no longer available for making electrical contact when organic materials are used. This manufacturing challenge is a barrier to transform the technology for industrialization. Therefore, improvements are needed in the field.

### SUMMARY

According to one embodiment, a low heat flux flexible thermoelectric generator woven with semiconducting strings is disclosed. The thermoelectric strings have a repeated structure of (metal)-(p-type semiconductor)-(metal)-(n-type semiconductor) materials in the same order and are formulated with a continuous structure for a module. In the woven structure, the thermoelectric strings are the warp threads and the insulator strings are the weft yarns. The p-type and n-type stripes are aligned to the same dimensions. A metal terminal at the end of the strings provides the electrical connections in a series with a serpentine manner. Two electrical insulating films laminated on the top and bottom of this woven structure conduct the surface heat to the metal junctions on both the hot and cold sides.

According to another embodiment, a thermoelectric generator is disclosed, comprising a plurality of insulating strings, a plurality of thermoelectric strings woven as warped lines through the insulating strings, the insulating strings serving as weft lines, the thermoelectric strings comprising alternating segments of a first semiconducting material and a second semiconducting material, the first semiconducting material and the second semiconducting material having differing electro-chemical potentials, the first and second semiconducting material segments joined by a conductive contact, a cold-side substrate connected to a first plurality of the conductive contacts, and a hot-side substrate connected to a second plurality of the conductive contacts. The first and second semiconductive materials may comprise bismuth-telluride (Bi2Te3). The first thermoelectric material may comprise p-type bismuth-telluride and the second thermoelectric material may comprise n-type bismuth-telluride. The cold-side substrate may comprise a plurality of surface extensions. The thermoelectric strings may be substantially perpendicular to the insulating strings. The thermoelectric strings may comprise a insulating inner core, with the first and second semiconductive materials surrounding the inner core. The thermoelectric generator may comprise a plurality of conductive terminals connecting ends of the thermoelectric strings in a serpentine configuration.

### BRIEF DESCRIPTION OF THE DRAWINGS

FIG. 1A shows a cut-away schematic of a p=m=n=m segment of a thermoelectric string according to one embodiment.

FIG. 1B shows a cut-away schematic of a p=m=n=m segment of a thermoelectric string with a glass fiber core according to a further embodiment.

FIG. 2A shows a schematic side view of a woven structure with thermoelectric strings according to one embodiment.

FIG. 2B shows a schematic top view of a woven structure with thermoelectric strings according to one embodiment.

FIG. 3 shows a schematic of an end string termination and connecting sequence of strings according to one embodiment.

FIG. 4A shows a side view of an example geometry and dimensions of the woven structure of FIG. 2.

FIG. 4B shows a top view of an example geometry and dimensions of the woven structure of FIG. 2.

FIG. 5 shows n plot of power output per unit area for the device of FIG. 2 in an example implementation.

FIG. 6 shows a plot of material cost per unit power output for the device of FIG. 2 in an example implementation.

FIG. 7 shows a pin-fin surface on the cold side film for the thermoelectric module of FIG. 2 according to one embodiment.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

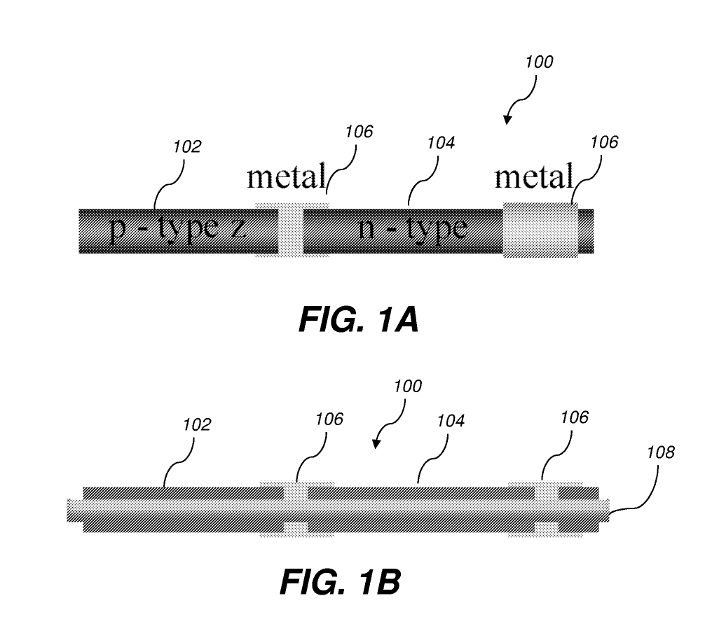

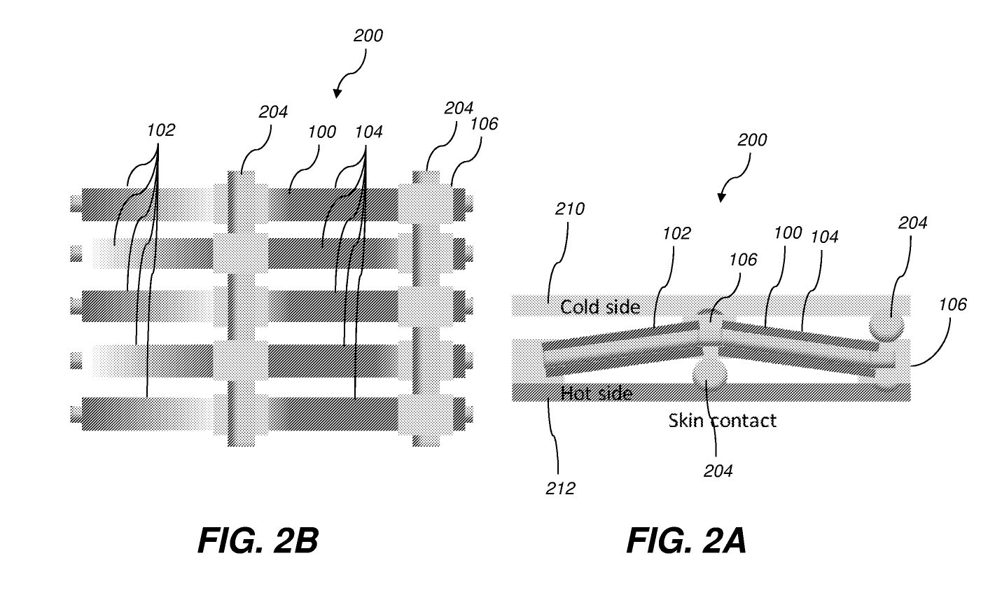

FIGS. 1A and 1B show a thermoelectric string 100 which contains a repeating series of thermoelectric legs 102 (p-type semiconductor) and 104 (n-type semiconductor) with electrical Ohmic metal contacts 106, which are scalable for manufacturing. The possibility of maintaining the mechanical strength for local bending in a weave can be satisfied by having glass fiber 108 or other insulating material as the core of the string as shown in FIG. 1B. The metal junction connecting p- and n-type materials preferably has a certain area ranging from 10-20% of the length of the semiconductor, although in other embodiments the may be 5-40%. One p-metal-n-metal segment has two contacts as shown in FIG. 2A. The contact between p- and n-types should contact the hot side (e.g., human skin), while the other side should contact the cold side (heat sink/ambient air) as shown in FIG. 2A. The pitch variation is minimized in repeating segments of the string when the string is woven into a repeating structure as discussed herein. The thermoelectric legs 102 and 104 preferably comprise p-type and n-type bismuth-telluride (Bi₂Te₃), respectively, although other types of material pairs that have different electro-chemical potentials may be used to achieve the thermoelectric effect.

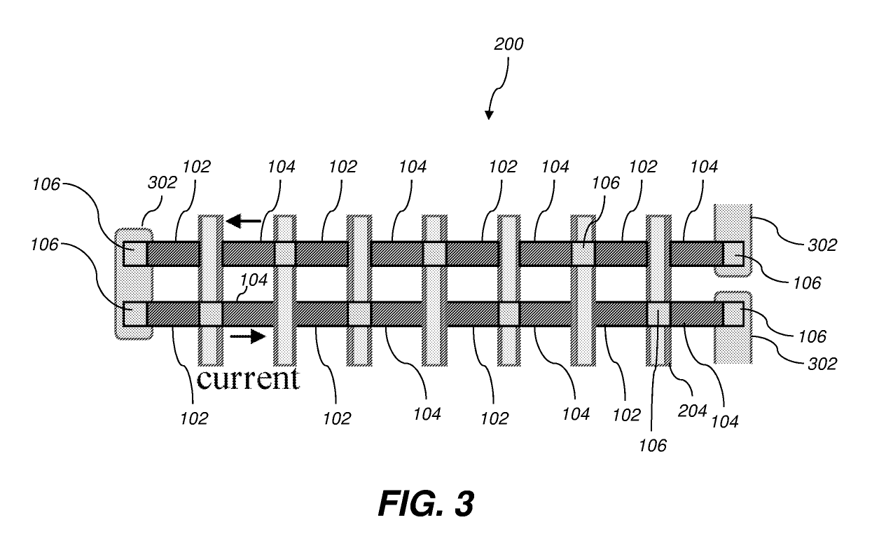

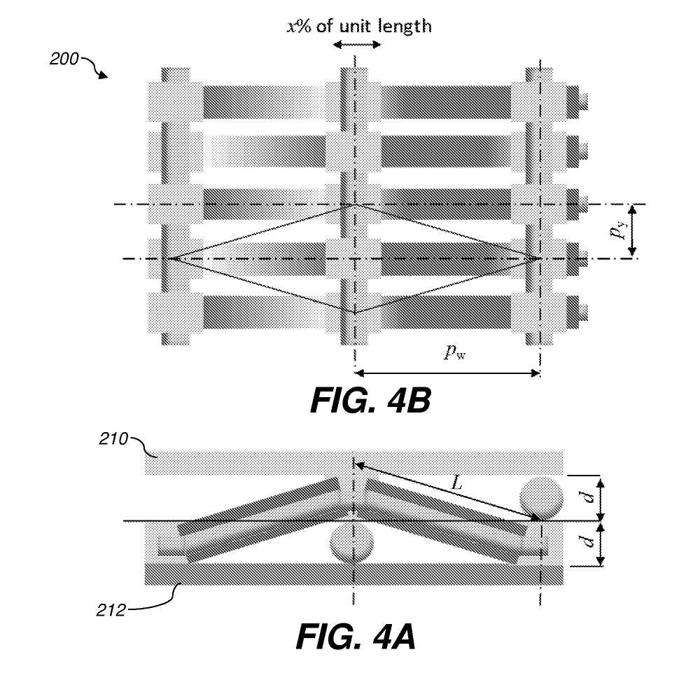

The thermoelectric string 100 of FIGS. 1A and 1B may be woven into a structure 200 as shown in FIGS. 2A (side view) and 2B (top view) according to one embodiment. The thermoelectric string itself does not work as the thermoelectric generator until it makes the thermal contacts properly, for example by contacting the cold side substrate 210 and the hot side substrate 212. The substrates 210 and 212 also act as thermal spreaders and may be implemented in one embodiment as thermal films. The woven structure 200 of FIG. 2 provides a repeating position for the hot and cold contacts so that the contacts are aligned on one side for hot and the other side for cold. In this example, all of the strings 100 are placed in parallel to comprise warp threads, while the weft lines crossing each other with the thermoelectric warp strings are simple strings 204 made of an insulating material, which in one embodiment may be glass fiber. Other insulating materials may also be used for the weft portions. As a result, all metal contact in the same string sequence is located on one side while all the other contact is on the other side as shown in FIGS. 2A and 2B. With this configuration, the electrical current along the strings flows in a serpentine manner as shown in FIG. 3. Hence, both ends of the strings 100 should be carefully connected and terminated at terminals 302 as shown in FIG. 3. The thickness of the strings 204 and the other components is preferably chosen so that the angle between the members 102 (or 104) and the substrate 210 (or 212) is between 10 and 30 degrees, although angles as low as two degrees and as large as 70 degrees may also be used depending on the needs of the particular application.

According to one example, a performance calculation of the woven thermoelectric structure 200 is based on human body heat recovery. The skin surface is assumed to maintain a temperature of 35° C., while the ambient temperature is 25° C. The hot side contact's effective heat transfer coefficient is 153 W/mK based on the fingertip contact example. The heat transfer coefficient for the air cooling side is 4 W/mK based on the 40 W/m² heat dissipation at the static mode. This is nearly the same as the correlation for the natural convection along the vertically oriented wall considering the characteristic length if the wall is in the order of 10 cm.

The material properties of the thermoelectric materials include the thermal conductivity 0.5 W/mK, the electrical conductivity 1.27 e+5 1/Ω.m, and the Seebeck coefficient 80 μV/K. The thermal conductivity of the laminate films are 0.16 W/m.K and the gap is filled by air 0.026 W/m.K. The specific contact resistance 1 e-5 Ω.cm² assumes one order of magnitude larger than an ordinal contact resistance.

The model is based on conventional π-configuration including thermal and electrical parasitic losses with thermal spreading and electrical contact and series resistances. The change needed for this woven configuration is only one point for the parallel thermal conductive heat loss through the gap between the two films (substrates 210 and 212). To calculate the correct thermal conductance of the gap, whether the gap is filled in or not, the conductivity of the gap fill material virtually increases by the ratio (leg length)/(gap height). Fortunately, there is no thermal conduction in a lateral direction in the cross-plane since the heat conduction is considered one dimensional across the thermoelectric leg.

Assumptions made for this calculation:
1. Number of legs: 100 per 1 cm²
2. The gap filled with air and radiation thermal cross talk between the laminates is negligible (due to very small temperature differences).
3. The electrical contact is similar to the ordinal thermoelectric modules but the series resistance is extremely small due to the string structure.
4. The thickness of the outer shell film laminates is 70 microns each

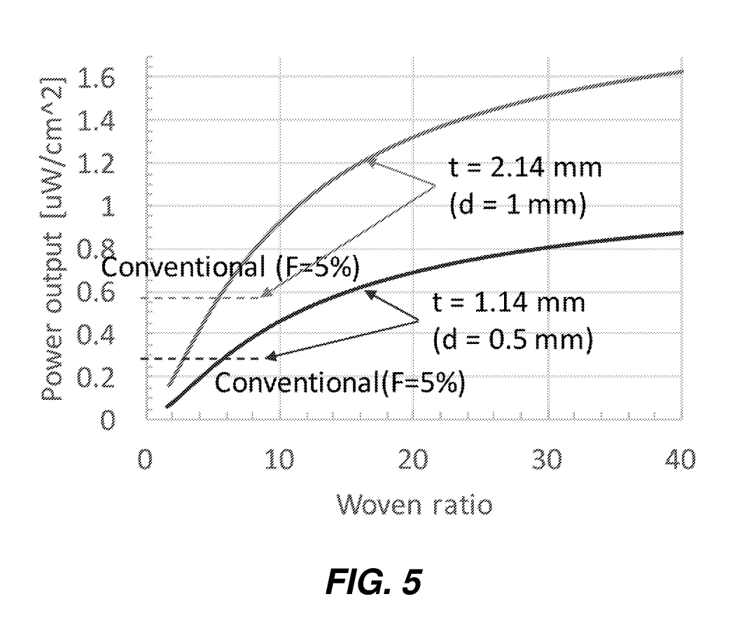

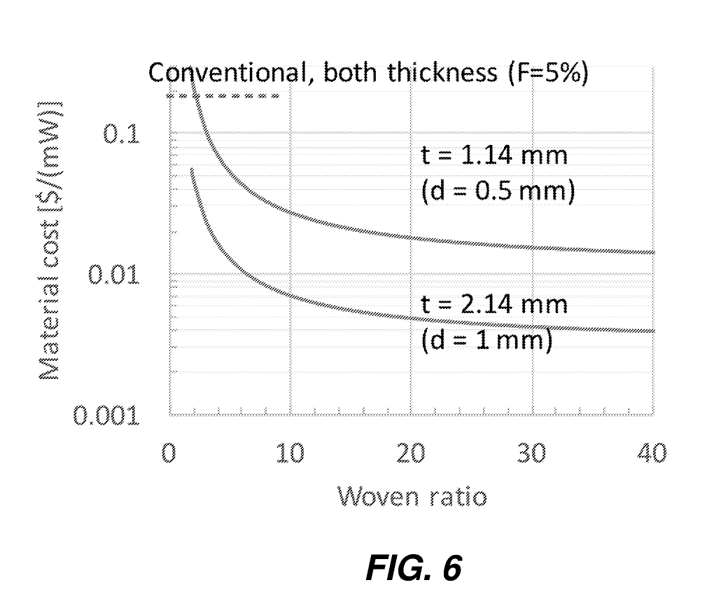

The effective fill factor F is found as

$$F = \frac{x ( L / d )}{2 {p}_{y} {p}_{w}} {d}^{2}$$

where, L is the actual leg length, d is the string diameter, p_{w} is the half pitch between the contacts on a film substrate along the leg length direction, and p_{y} is the warp thread pitch. FIGS. 5 and 6 show the power output [μW/cm²] and power cost [$/(mW)], respectively. Both are functions of the woven ratio, which is L/d. In this performance calculation, two different diameters (0.5 mm and 1.0 mm) of the strings are investigated. The performance of the conventional thermoelectric modules with a fill factor of 5% and the same module thickness are also on the plot. The densities are 8900 kg/m³ for the thermoelectric, and 1300 kg/m³ for films and the material prices are 100 $/kg and 3 $/kg, respectively.

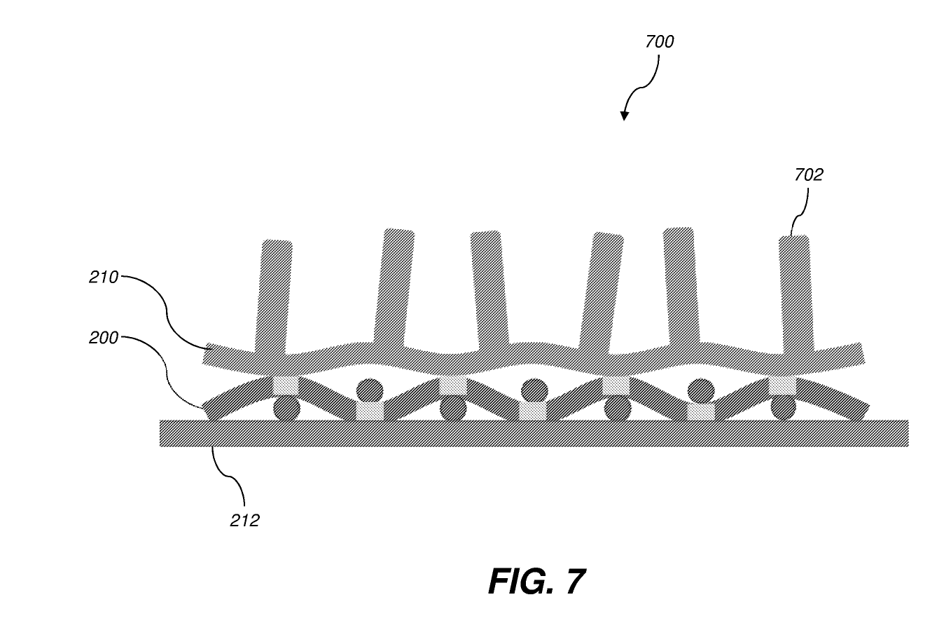

The above calculation is specifically based on the body heat, but there are a variety of types of low-grade waste heat that may be harvested using the structure 200, including residential/commercial buildings, or industrial waste. For some of the cases, the surface of the hot substance may have a cylindrical or 3-D curvature. This flexible low fill factor and long leg design is virtually scalable for any temperature difference especially in low heat flux conditions or poor heat transfer conditions. Another embodiment of the present disclosure includes an embedded heat sink with the thermoelectric generator device. FIG. 7 shows a structure 700 similar to structure 200 of FIG. 2, which includes surface extensions 702 having a pin or fin structure for the cold side substrate 210. The bottom substrate 212 contacts the skin surface. The illustrated embodiment has one surface extension 702 per contact, although in other embodiments, multiple surface extensions 702 per contact may be used as well. The surface extensions 702 may comprise cylindrical pins, planar fins, or other cross-sectional shapes depending on the needs of the application. The surface extensions may 702 be rigid or flexible.

The above woven thermoelectric generators with p- and n-type semiconductor strings may fit the flexible power generator not only for human body heat recovery but also for some types of low grade heat recovery from the curved surface. The weave structure could allow scalable manufacturing. Thermal resistance matching is an important key to obtaining the maximum power output for the given temperature reservoirs, while most of the prior art flexible thermoelectric modules do not match the criteria. The presently disclosed woven structure solves the problem of keeping the longer thermoelectric element with a smaller fill factor fit for a confined gap space in a low profile thermoelectric generator module. The above sample thermal calculation results suggest a 2-3 fold increase in output power and a significantly lower cost compared to that of prior art designs for applications in body heat recovery. The disclosed device provides flexibility to allow the device to conform to a curved surface.

Those skilled in the art will recognize that numerous modifications can be made to the specific implementations described above. The implementations should not be limited to the particular limitations described. Other implementations may be possible.

1. A thermoelectric generator, comprising:
a plurality of insulating strings;
a plurality of thermoelectric strings woven as warped lines through the insulating strings, the insulating strings serving as weft lines, the thermoelectric strings comprising alternating segments of a first semiconducting material and a second semiconducting material, the first semiconducting material and the second semiconducting material having differing electro-chemical potentials, the first and second semiconducting material segments joined by a conductive contact;
a cold-side substrate connected to a first plurality of the conductive contacts; and
a hot-side substrate connected to a second plurality of the conductive contacts.

2. The thermoelectric generator of claim 1, wherein the first and second semiconductive materials comprise bismuth-telluride (Bi₂Te₃).

3. The thermoelectric generator of claim 2, wherein the first thermoelectric material comprises p-type bismuth-telluride and the second thermoelectric material comprises n-type bismuth-telluride.

4. The thermoelectric generator of claim 1, wherein the cold-side substrate comprises a plurality of surface extensions.

5. The thermoelectric generator of claim 4, wherein the surface extensions are rigid.

6. The thermoelectric generator of claim 4, wherein the surface extensions are flexible.

7. The thermoelectric generator of claim 4, wherein the surface extensions comprise planar fins.

8. The thermoelectric generator of claim 4, wherein the surface extensions comprise cylindrical pins.

9. The thermoelectric generator of claim 1, wherein the hot-side comprises a plurality of flexible soft material contacting to skin surfaces.

10. The thermoelectric generator of claim 1, wherein the thermoelectric strings are substantially perpendicular to the insulating strings.

11. The thermoelectric generator of claim 1, wherein the thermoelectric strings comprise a insulating inner core, the first and second semiconductive materials surrounding the inner core.

12. The thermoelectric generator of claim 1, further comprising a plurality of conductive terminals connecting ends of the thermoelectric strings in a serpentine configuration.

13. The thermoelectric generator of claim 3, wherein the cold-side substrate comprises a plurality of surface extensions.

14. The thermoelectric generator of claim 13, wherein the hot-side comprises a plurality of flexible soft material contacting to skin surfaces.

15. The thermoelectric generator of claim 14, wherein the thermoelectric strings are substantially perpendicular to the insulating strings.

16. The thermoelectric generator of claim 15, wherein the thermoelectric strings comprise a insulating inner core, the first and second semiconductive materials surrounding the inner core.

17. The thermoelectric generator of claim 16, further comprising a plurality of conductive terminals connecting ends of the thermoelectric strings in a serpentine configuration.

18. The thermoelectric generator of claim 4, wherein the hot-side comprises a plurality of flexible soft material contacting to skin surfaces.

19. The thermoelectric generator of claim 19, wherein the thermoelectric strings are substantially perpendicular to the insulating strings.

20. The thermoelectric generator of claim 19, wherein the thermoelectric strings comprise a insulating inner core, the first and second semiconductive materials surrounding the inner core.
